(19) United States
(12) Patent Application Publication
(10) Pub. No.: US 2010/0221917 A1
(43) Pub. Date: Sep. 2, 2010

(54) METHOD OF MANUFACTURING SILICON CARBIDE SEMICONDUCTOR DEVICE

(75) Inventor: Takeyoshi Masuda, Osaka (JP)

Correspondence Address: FISH & RICHARDSON P.C., P.O. BOX 1022, MINNEAPOLIS, MN, 55440-1022, US

(73) Assignee: SUMITOMO ELECTRIC INDUSTRIES, LTD., Osaka-shi, Osaka (JP)

(21) Appl. No.: 12/161,832

(22) PCT Filed: Dec. 6, 2006
(86) PCT No.: PCT/JP2006/324347

§ 371 Date: Jul. 23, 2008

(30) Foreign Application Priority Data
Jan. 30, 2006 (JP) 2006-020060

(51) Int. Cl. H01L 21/04

(52) U.S. Cl. 438/692; 438/779; 438/767; 257/E21.066

(57) ABSTRACT

A method of manufacturing a silicon carbide semiconductor device having low interface state density in an interface region between a gate insulating film and a silicon carbide layer is provided. An epitaxially grown layer is grown on a 4H-SiC substrate, and thereafter ion implantation is performed to form a p well region, a source region and a p+ contact region that are ion implantation layers. Thereafter, using thermal oxidation or CVD, the gate insulating film formed by a silicon oxide film is formed on the p well region, the source region and the p+ contact region. Then, plasma is generated using a gas containing N2O, which is the gas containing at least any one of oxygen and nitrogen, so as to expose the gate insulating film to plasma.

### TECHNICAL FIELD

The present invention relates to a method of manufacturing a silicon carbide semiconductor device such as an MOSFET, having a gate insulating film low in interface state density.

### BACKGROUND ART

Semiconductor devices such as a transistor and a diode formed with a silicon carbide substrate (SiC substrate) composed of silicon (Si) and carbon (C) bonded to each other at a composition ratio of 1:1 have been expected to go into actual use as power devices. As silicon carbide is a wide bandgap semiconductor, its breakdown electric field is higher than that of silicon by one order of magnitude. Accordingly, even if a depletion layer at a pn junction or a Schottky junction has a smaller thickness, a high peak inverse voltage can be maintained. Here, as use of the silicon carbide substrate permits smaller thickness of the device and higher doping concentration, implementation of a power device having a low ON resistance, a high withstand voltage, and low loss has been expected. It is noted that the silicon carbide substrate herein encompasses any substrate obtained by epitaxially growing a silicon carbide crystal layer on a substrate composed of silicon carbide crystals or a material different from silicon carbide.

Meanwhile, as compared with an MOSFET (Metal Oxide Semiconductor Field Effect Transistor) including a silicon substrate, an MOSFET including the silicon carbide substrate is disadvantageous in poor characteristics of a silicon oxide film serving as a gate insulating film, for the following reasons. Basically, as a large amount of carbon remains in a thermal oxidation film on the silicon carbide substrate, C—C bonds or dangling bonds are present, and consequently, interface state density in an interface region between the thermal oxidation film and a silicon carbide layer is high.

For addressing such a disadvantage, according to Japanese National Patent Publication No. 2004-511101 (Patent Document 1), for example, lower interface state density in an interface region between an oxide layer and a silicon carbide layer is achieved by oxidizing the silicon carbide layer in dinitrogen monoxide (N₂O) and annealing the oxide layer on the silicon carbide layer in an N₂O atmosphere.

### Patent Document 1: Japanese National Patent Publication No. 2004-511101

### DISCLOSURE OF THE INVENTION

### Problems to be Solved by the Invention

According to Patent Document 1, nitrogen monoxide (NO) generated as a result of thermal decomposition through annealing in N₂O inactivates dangling bond of Si, C that is present in the interface region between an oxide film (oxide layer) and a semiconductor layer. Accordingly, the interface state serving as electron trap is lowered and carrier mobility is improved. According to the technique in Patent Document 1, however, reaction between N₂O and SiC should be caused at a temperature of 1100° C. or higher, and therefore Patent Document 1 is disadvantageous in poor throughput due to a long time required for temperature increase and decrease in an annealing furnace as well as in difficulty in maintaining uniformity of a temperature within a wafer.

An object of the present invention is to provide a method of manufacturing a silicon carbide semiconductor device having low interface state density with high throughput.

### Means for Solving the Problems

A method of manufacturing a silicon carbide semiconductor device according to the present invention includes: an oxide film forming step of forming an oxide film serving as a gate insulating film on a silicon carbide layer formed on a substrate; and a plasma exposure step of exposing the oxide film to plasma generated by using a gas containing at least any one of nitrogen element (N) and oxygen element (O), after the oxide film forming step.

According to this method, functions such as inactivation of a dangling bond by an N atom and breaking of C—C bond by an O atom are attained, and therefore, interface state density in an interface region between an oxide film and a silicon carbide layer can be lowered through treatment at a relatively low temperature. In addition, as higher uniformity of plasma treatment within a wafer is more likely in the plasma exposure step than in annealing treatment, variation in the interface state density is also smaller. Therefore, in addition to improvement in channel mobility and lowering in a leakage current in an MOSFET or the like, variation in a threshold voltage of the MOSFET or the like is also smaller. Moreover, as the plasma exposure step can be performed at a relatively low temperature, throughput is also improved.

In the method of manufacturing a silicon carbide semiconductor device above, in the plasma exposure step, at least one gas selected from among a gas containing nitrogen molecules (N₂), a gas containing oxygen molecules (O₂), and a gas containing ozone (O₃) is preferably employed as the gas containing at least any one of nitrogen element and oxygen element. Alternatively, a gas containing nitrogen element and oxygen element is preferably employed as the gas containing at least any one of nitrogen element and oxygen element. Here, at least one gas selected from a gas containing dinitrogen monoxide (N₂O) and a gas containing nitrogen oxide (NOx) is preferably employed as the gas containing nitrogen element and oxygen element.

In the method of manufacturing a silicon carbide semiconductor device above, in the oxide film forming step, a silicon oxide film is preferably formed as the oxide film by heating the silicon carbide layer in an atmosphere containing at least oxygen element. In forming the gate insulating film, by forming the silicon oxide film through thermal oxidation in which the silicon carbide layer is heated to a high temperature in an atmosphere containing at least oxygen element, information on a crystalline state of the underlying silicon carbide layer is taken over to the silicon oxide film. The gate insulating film well adapted to the underlying layer is thus obtained. Here, a temperature for thermal oxidation treatment is preferably in a range from at least 1250° C. to at most 1400° C.

In the oxide film forming step, the oxide film is preferably formed with chemical vapor deposition (CVD). In forming the gate insulating film, by forming the oxide film with CVD, the gate insulating film relatively low in the interface state density in the region of interface with the underlying silicon carbide layer is obtained.

The method of manufacturing a silicon carbide semiconductor device preferably further includes the step of planarizing the silicon carbide layer with chemical mechanical planarization (CMP) prior to the oxide film forming step. By planarizing the silicon carbide layer with CMP prior to forming the gate insulating film, distribution of the interface state density is made uniform, and the silicon carbide semiconductor device smaller in variation in the threshold voltage is obtained.

### EFFECTS OF THE INVENTION

According to the method of manufacturing a silicon carbide semiconductor device of the present invention, the silicon carbide semiconductor device having low interface state density in the interface region between the gate insulating film and the silicon carbide layer can be obtained.

### BRIEF DESCRIPTION OF THE DRAWINGS

FIG. 1 is a cross-sectional view showing a step of manufacturing an MOSFET in an embodiment.

FIG. 2 is a cross-sectional view showing a step of manufacturing the MOSFET in the embodiment.

FIG. 3 is a cross-sectional view showing a step of manufacturing the MOSFET in the embodiment.

FIG. 4 is a cross-sectional view showing a step of manufacturing the MOSFET in the embodiment.

FIG. 5 is a cross-sectional view showing a step of manufacturing the MOSFET in the embodiment.

FIG. 6 is a cross-sectional view showing a step of manufacturing the MOSFET in the embodiment.

FIG. 7 is a perspective view schematically showing a structure of a plasma apparatus used in the embodiment.

FIG. 8 illustrates data showing difference in dependency of channel mobility on a gate voltage, depending on whether plasma treatment is performed or not.

### DESCRIPTION OF THE REFERENCE SIGNS

10 4H-SiC substrate; 11 epitaxially grown layer; 12 p well region; 12a channel region; 13 source region; 15 p⁺ contact region; 20 gate insulating film; 21 source electrode; 22 gate electrode; 23 drain electrode; 50 plasma apparatus; 51 chamber; 52 tunnel; 53 upper electrode; 54 lower electrode; 61 wafer; and 62 wafer carrier.

### BEST MODES FOR CARRYING OUT THE INVENTION

### Embodiment

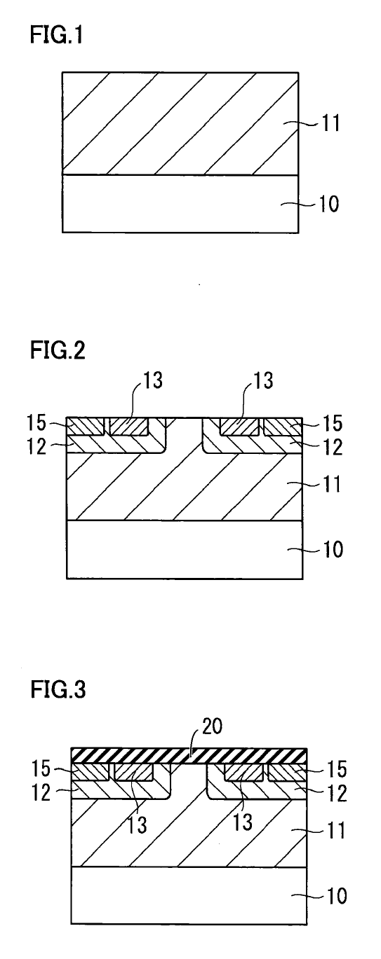

FIGS. 1 to 6 are cross-sectional views showing steps of manufacturing an MOSFET representing a silicon carbide semiconductor device in an embodiment.

Though FIGS. 1 to 6 show solely two transistor cells representing a part of a vertical MOSFET, a large number of transistor cells are integrated to configure one vertical MOSFET.

In the step shown in FIG. 1, an n-type 4H (hexagonal)-SiC (4 represents the number of layers stacked in one period) substrate 10, for example, having a resistivity of 0.02 Ωcm and a thickness of 400 μm, and having a (0001) face at an off angle of approximately 8° in [11-20] direction as a main surface is prepared. Then, using CVD epitaxial growth including in-situ doping, an epitaxially grown layer 11, for example, containing an n-type dopant in a concentration of approximately 5×10¹⁵ cm⁻³ and having a thickness of approximately 10 μm is grown on 4H-SiC substrate 10. An outermost surface of epitaxially grown layer 11 immediately after epitaxial growth has an average surface roughness Ra, for example, of approximately 0.2 nm to 0.3 nm. It is noted herein that an individual orientation and an individual face are shown with [ ] and ( ), respectively.

Thereafter, in the step shown in FIG. 2, using ion implantation, a p well region 12, for example, containing a p-type dopant in a concentration of approximately 1×10¹⁷ cm⁻³ and having a thickness (depth) of approximately 1.0 μm is formed in a part of a surface portion of epitaxially grown layer 11. Further using ion implantation, a source region 13, for example, containing an n-type dopant in a concentration of 1×10¹⁹ cm⁻³ and having a thickness (depth) of approximately 0.3 μm and a p⁺ contact region 15, for example, containing a p-type dopant in a concentration of 5×10¹⁹ cm⁻³ and having a thickness (depth) of approximately 0.3 μm are formed in each part of the surface portion of p well region 12. Here, the temperature of 4H-SiC substrate 10 and epitaxially grown layer 11 during ion implantation is set, for example, to 500° C. Thereafter, an abrasive mainly containing colloidal silica is used to perform CMP (chemical mechanical planarization), to thereby remove the surface portion of the substrate, for example, by approximately 1 nm to 5 nm. The outermost surface of epitaxially grown layer 11 immediately after CMP has average surface roughness Ra, for example, in a range from approximately 0.1 nm to 0.5 nm. Though not shown, in general, after these steps, a sacrificial oxide film is formed on the substrate using thermal oxidation, and thereafter the sacrificial oxide film is removed, and then the process proceeds to a next step.

Thereafter, in the step shown in FIG. 3, for example, using thermal oxidation, a gate insulating film 20 formed as the silicon oxide film having a thickness of approximately 50 nm is formed on 4H-SiC substrate 10. Here, gate insulating film 20 is preferably formed through heating to a high temperature in an atmosphere containing at least oxygen element (O). Here, for example, O₂, O₃, N₂O, and the like may be employed as the gas containing oxygen element. Through heating in the atmosphere containing oxygen element, an oxide film higher in quality than a film formed with sputtering or CVD can be obtained. Heating to a high temperature in a range from at least 1250° C. to at most 1400° C. is preferably performed. Heating to a high temperature not lower than 1250° C. can bring about lower interface state density at an interface between gate insulating film 20 and each layer within epitaxially grown layer 11 (in particular, p well region 12). Heating to a high temperature not higher than 1400° C. can suppress roughness of the surface of each layer within epitaxially grown layer 11. By performing thermal oxidation in the atmosphere containing oxygen element and nitrogen element, the interface state density at the interface between gate insulating film 20 and each layer within epitaxially grown layer 11 (in particular, p well region 12) can also be lowered. By thus employing the gas containing nitrogen element and oxygen element (such as N₂O and NO), the following function and effect is obtained, as compared with oxidation using solely oxygen element. Specifically, as remaining carbon from which the interface state originates is nitrided to attain a passivation function, further lower interface state density can be achieved.

Instead of thermal oxidation, for example, CVD (chemical vapor deposition) may be employed. As the underlying silicon carbide layer is hardly altered in CVD, gate insulating film 20 achieving relatively low interface state density in the region of interface with the underlying silicon carbide layer is obtained. Therefore, as far as only an effect to lower the interface state density is concerned, CVD is preferred.

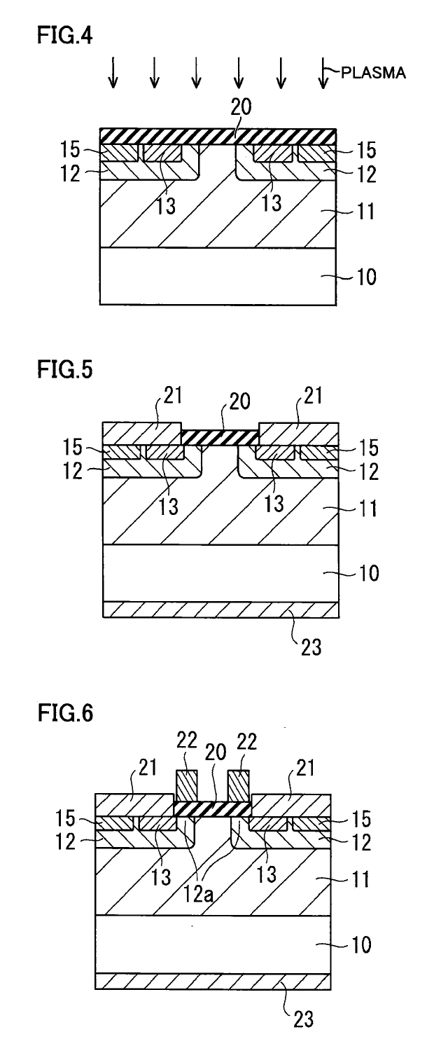

Thereafter, in the step shown in FIG. 4, with the use of a barrel type plasma apparatus, a gas containing at least any one of nitrogen element and oxygen element is employed to generate plasma for plasma treatment of gate insulating film 20 (plasma exposure step). In the plasma exposure step, for example, at least one gas selected from among a gas containing N₂, a gas containing O₂, and a gas containing O₃ is employed as the gas containing at least any one nitrogen element and oxygen element. Thus, passivation or removal (elimination) of carbon remaining at the interface between the oxide film and each layer within epitaxially grown layer 11 can be achieved. Alternatively, for example, a gas containing nitrogen element and oxygen element is employed as the gas containing at least any one of nitrogen element and oxygen element. By doing so, passivation or removal (elimination) of carbon remaining at the interface between the oxide film and each layer within epitaxially grown layer 11 can also similarly be achieved. Here, for example, at least one gas selected from a gas containing N₂ and a gas containing NOx is employed as the gas containing nitrogen element and oxygen element. By doing so, passivation or removal (elimination) of carbon remaining at the interface between the oxide film and each layer within epitaxially grown layer 11 can also similarly be achieved. If the gas containing nitrogen element and oxygen element is employed, for example, a partial pressure (ratio) between nitrogen element and oxygen element can be set to 1:1.

The plasma exposure step is not particularly limited, so long as plasma is generated by using the gas containing at least any one of nitrogen element and oxygen element. The gas containing at least any one of nitrogen element and oxygen element may further contain, for example, hydrogen or the like.

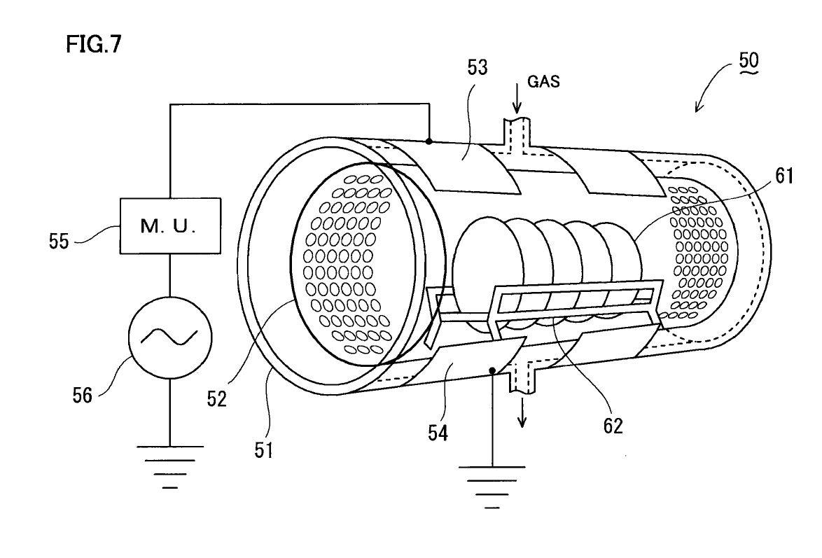

FIG. 7 is a perspective view schematically showing a structure of a plasma apparatus 50 used in the embodiment. Plasma apparatus 50 includes a chamber 51 formed with a quartz tube or the like, a tunnel 52 formed with an aluminum mesh tube or the like provided in chamber 51, an upper electrode 53 attached to a ceiling portion of chamber 51, and a lower electrode 54 attached to a bottom portion of chamber 51. Upper electrode 53 is connected to a high-frequency power supply with a matching unit 55 being interposed, and lower electrode 54 is connected to ground. A plurality of wafers 61 vertically placed on a wafer carrier 62 are arranged in tunnel 52. In the present embodiment, for example, plasma is generated under such conditions as power of 300 W and frequency of 13.56 MHz, while a gas obtained by diluting N₂O with a nitrogen gas to a concentration of approximately 10 volume % flows through chamber 51. For example, the temperature in chamber 51 is set to approximately 100° C. and a time period during which exposure to plasma is performed is set to approximately 60 minutes.

Thereafter, in the step shown in FIG. 5, a portion of gate insulating film 20 located above source region 13 and p⁺ contact region 15 is removed, and thereafter, a source electrode 21 formed by a nickel (Ni) film having a thickness of approximately 0.1 μm is formed in a region from which gate insulating film 20 has been removed, for example, with a lift-off method.

Thereafter, in the step shown in FIG. 6, for example, by performing heat treatment at a temperature of 975° C. for 2 minutes in an argon (Ar) atmosphere, a contact characteristic between Ni composing source electrode 21 and a drain electrode 23 and silicon carbide composing the underlying layer (source region 13, p⁺contact region 15 and 4H-SiC substrate 10) is changed from Schottky contact to Ohmic contact. Thereafter, a gate electrode 22 composed of Al is formed on gate insulating film 20, spaced apart from source electrode 21.

Through the manufacturing steps above, an n-channel vertical MOSFET attaining a function as a power device is formed. In the vertical MOSFET, a region located in the uppermost portion of p well region 12 and under gate electrode 22 with gate insulating film 20 being interposed attains a function as a channel region 12a. When the MOSFET turns on, the current supplied from drain electrode 23 flows in the vertical direction from 4H-SiC substrate 10 to the uppermost portion of epitaxially grown layer 11, and thereafter the current reaches source region 13 through channel region 12a in the uppermost portion of p well region 12. Here, in channel region 12a, electrons, i.e., carriers, run from source region 13 toward the uppermost portion of epitaxially grown layer 11. Mobility of electrons in channel region 12a refers to channel mobility.

In the step of forming the gate oxide film shown in FIG. 3 of the present embodiment, CO or CO₂ volatilizes as a result of bonding between C atoms in epitaxially grown layer 11 (SiC layer) and O atoms, while a silicon oxide film (SiO₂) is formed as a result of bonding between Si atoms with O atoms. Here, unlike thermal oxidation at the surface of an Si layer, a large number of C atoms remain after thermal oxidation treatment of the surface of the SiC layer. Accordingly, a large number of dangling bonds of Si, C or C—C bonds representing bonding between C atoms are present in the interface region between the gate oxide film and the silicon carbide layer. Consequently, a large number of interface state densities are present in a region around the interface between the gate oxide film and the silicon carbide layer.

Here, by exposing gate insulating film 20 to plasma generated by using the gas containing oxygen element, a function of breaking of C—C bond by O atom is attained. In addition, by exposing gate insulating film 20 to plasma generated by using the gas containing nitrogen, a function to inactivate the dangling bond of Si, C (termination function) is attained. Any of these functions contributes to lower interface state density in the interface region between gate insulating film 20 and channel region 12a. Consequently, channel mobility of the MOSFET is improved and leakage current is also decreased. In particular, in the present embodiment, as the gate insulating film is exposed to plasma generated by using the gas containing N₂O which is the gas containing oxygen and nitrogen, the function to break C—C bond and the function to inactivate the dangling bond are both attained, a function to lower the interface density is further noticeable.

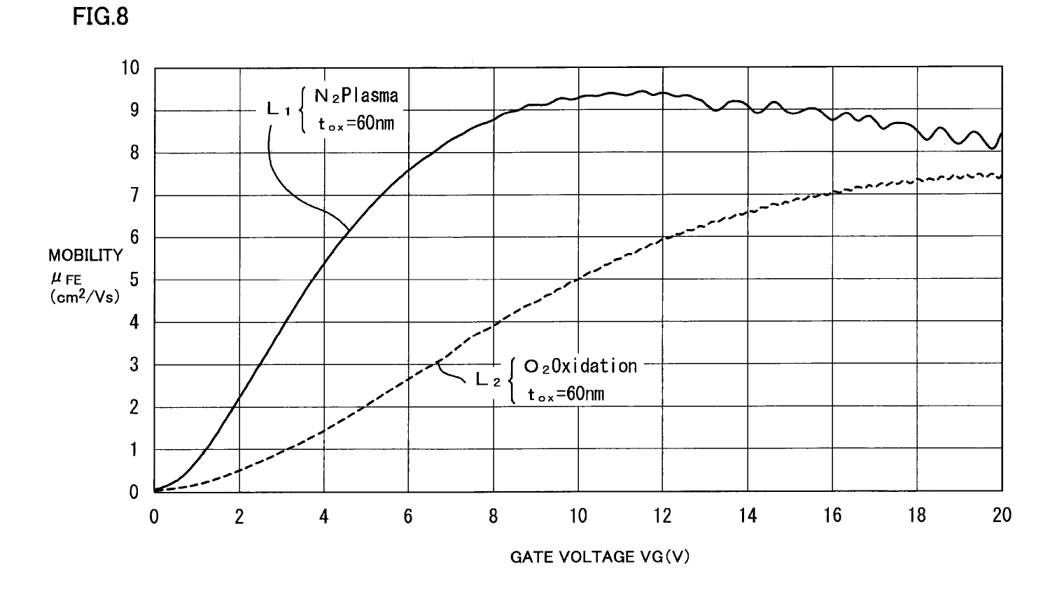

FIG. 8 illustrates data showing difference in dependency of channel mobility on a gate voltage, depending on whether plasma treatment is performed or not. Data curves L1 and L2 in FIG. 8 represent channel mobility in an MOSFET sample (thickness of gate insulating film of 60 nm) that has been subjected to plasma treatment (in the case of this sample, N₂ plasma treatment) after the gate insulating film is formed and in an MOSFET sample (thickness of gate insulating film of 60 nm) that has simply been subjected to thermal oxidation in O₂ atmosphere to form the gate insulating film. Here, the MOSFET samples were manufactured under the conditions described previously in connection with the steps shown in FIGS. 1 to 6. Here, average surface roughness Ra of epitaxially grown layer 11 was 10 nm, average surface roughness Ra of the outermost surface of epitaxially grown layer 11 immediately after CMP was 0.5 nm, and gate insulating film 20 was formed with thermal oxidation at 1300° C. by using O₂ as the gas containing oxygen element, or in the plasma exposure step, it was formed by using the gas obtained by diluting N₂O with the nitrogen gas to a concentration of 10 volume %. As shown in the figure, it can be seen that channel mobility noticeably improved by performing plasma treatment.

In addition, in the plasma treatment step shown in FIG. 4, the treatment temperature is set to approximately 100° C., and treatment at a high temperature around 1100° C. is not necessary as in the technique of Patent Document 1. Therefore, high throughput can also be maintained.

Moreover, according to the technique of Patent Document 1, as the treatment is performed at a high temperature around 1100° C., it is difficult to maintain uniform temperature distribution in the wafer, and variation in the interface state density within the wafer is significant. In contrast, according to the present invention, uniform treatment of the wafer with plasma can relatively easily be performed. As uniformity of the interface state density within the wafer is thus also high, variation in the threshold voltage of the MOSFET can be made smaller.

It is noted that data curves L1 and L2 shown in FIG. 8 were plotted in a graph by calculating mutual conductance based on characteristics of a gate voltage and a drain current when a drain voltage of 0.1V was applied and by finding field effect mobility.

In the step of manufacturing an MOSFET according to the present embodiment, the gas containing N₂O was employed as the atmosphere for plasma treatment. Here, by employing the gas containing at least any one of nitrogen element and oxygen element, the interface state density present in the interface region between gate insulating film 20 and epitaxially grown layer 11 can be lowered, and an effect of the present invention can thus be achieved. Specifically, a gas containing N₂, a gas containing O₂ or O₃, a gas containing NOx, a gas containing nitrogen element and oxygen element, and the like are exemplary gases containing at least any one of nitrogen element and oxygen element. By employing these gases, plasma containing at least any one of oxygen element and nitrogen element can be generated.

A barrel type plasma generation apparatus is more advantageous as a plasma generation apparatus than a parallel plate type plasma generation apparatus, because damage to a gate insulating film and the like is less likely. Damage can be suppressed also by employing ICP (Inductively Coupled Plasma).

In the step shown in FIG. 2, thermal oxidation is preferably performed at a temperature in a range from at least 1250° C. to at most 1400° C. This is because, as the temperature is higher, an effect to lower the interface state density is greater. Here, an atmosphere containing O₂, an atmosphere containing NO₂, an atmosphere containing N₂O, or the like may be selected for use as the atmosphere.

### Other Embodiments

The structure in the embodiment of the present invention disclosed above is by way of illustration and the scope of the present invention is not limited by the scope of the description. The scope of the present invention is defined by the terms of the claims, and is intended to include any modifications within the scope and meaning equivalent to the terms of the claims.

In the embodiment above, an example in which the silicon carbide semiconductor device according to the present invention is applied to an MOSFET (DMOSFET) has been described, however, the silicon carbide semiconductor device according to the present invention is also applicable to a VMOSFET, a UMOSFET, an IGBT, and the like.

In addition, in the embodiment above, an example in which the present invention is applied to an inversion mode MOSFET has been described, however, the present invention is applicable also to an accumulation mode MOSFET. Moreover, in the embodiment above, an example in which the present invention is applied to a vertical MOSFET has been described, however, the present invention is applicable also to a lateral MOSFET. Here, the drain region opposed to the source region with the channel region being interposed is formed in the surface portion of the epitaxially grown layer.

The substrate in the present invention is not limited to a 4H-SiC substrate, and an SiC substrate of a poly type different from 4H poly type, such as a 6H-SiC substrate (the number of layers stacked in one period is 6) or a substrate made of a material different from those for the SiC substrate, such as an Si substrate, may be adopted. For example, by applying the present invention also to a silicon carbide semiconductor device including a 3C-SiC epitaxially grown layer hetero-epitaxially grown on an Si substrate, an MOSFET small in variation in a threshold voltage or a Schottky diode of high withstand voltage can be obtained.

### INDUSTRIAL APPLICABILITY

The silicon carbide semiconductor device according to the present invention may be utilized for an MOSFET, an IGBT, and the like used as a power device or a high-frequency device.

1. A method of manufacturing a silicon carbide semiconductor device, comprising:
an oxide film forming step of forming an oxide film serving as a gate insulating film on a silicon carbide layer formed on a substrate; and
a plasma exposure step of exposing said oxide film to plasma generated by using a gas containing at least any one of nitrogen element and oxygen element, after said oxide film forming step.

2. The method of manufacturing a silicon carbide semiconductor device according to claim 1, wherein
in said plasma exposure step, at least one gas selected from among a gas containing nitrogen molecules, a gas containing oxygen molecules, and a gas containing ozone is employed as said gas containing at least any one of nitrogen element and oxygen element.

3. The method of manufacturing a silicon carbide semiconductor device according to claim 1, wherein
in said plasma exposure step, a gas containing nitrogen element and oxygen element is employed as said gas containing at least any one of nitrogen element and oxygen element.

4. The method of manufacturing a silicon carbide semiconductor device according to claim 3, wherein
in said plasma exposure step, at least one gas selected from a gas containing dinitrogen monoxide and a gas containing nitrogen oxide is employed as said gas containing nitrogen element and oxygen element.

5. The method of manufacturing a silicon carbide semiconductor device according to claim 1, wherein
in said oxide film forming step, a silicon oxide film is formed as said oxide film by heating said silicon carbide layer in an atmosphere containing at least oxygen element.

6. The method of manufacturing a silicon carbide semiconductor device according to claim 5, wherein
in said oxide film forming step, thermal oxidation is performed at a temperature in a range from at least 1250° C. to at most 1400° C.

7. The method of manufacturing a silicon carbide semiconductor device according to claim 1, wherein
in said oxide film forming step, said oxide film is formed with chemical vapor deposition.

8. The method of manufacturing a silicon carbide semiconductor device according to claim 1, further comprising the step of planarizing said silicon carbide layer with chemical mechanical planarization prior to said oxide film forming step.
